(19) United States
(12) Patent Application Publication
(10) Pub. No.: US 2010/0244831 A1
(43) Pub. Date: Sep. 30, 2010

(54) DYNAMIC MAGNETIC RESONANCE IMAGING (MRI) WITH ADAPTIVE IMAGE QUALITY

(75) Inventor: Daniel R. Elgort, New York, NY (US)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N.V., EINDHOVEN (NL)

(21) Appl. No.: 12/743,840

(22) PCT Filed: Dec. 10, 2008
(86) PCT No.: PCT/IB08/55193

§ 371 Date: May 20, 2010

Related U.S. Application Data
(60) Provisional application No. 61/014,465, filed on Dec. 18, 2007.

(51) Int. Cl. G01R 33/48

(52) U.S. Cl. 324/309

(57) ABSTRACT

A resonance imaging (MRI) apparatus (10), comprising: one or more transmitting coils (12) for generating a static magnetic field within which a subject (14) can be positioned and a probe (16) for insertion into, and movement through, the subject (14). The probe (16) includes a tracking element (26,28) in the form of two loop coils and an imaging coil (24). Processing means (22) are provided for receiving spatially encoded signals from the loop coils (26,28) and from the imaging coil (24). The tracking signals from the loop coils (26,28) are decoded to determine the relative position of the probe (16) within an image volume and the image to be displayed as adjusted accordingly corresponding to the relative position of the probe (16). The image signals from the imaging coil (24) are also decoded to generate an image for display, and the image to be displayed is updated dynamically as the probe (16) is moved within the subject (14) based on successive sets of tracking signals received from the tracking element (26,38) and successive sets of spatially encoded signals received from the imaging coil (24).

### FIELD OF THE INVENTION

This invention relates generally to Magnetic Resonance Imaging (MRI) and more specifically to a catheter-based MRI system with adaptive image quality, particularly but not necessarily exclusively suited to intravascular MR imaging.

### BACKGROUND OF THE INVENTION

It is well known to use Magnetic Resonance Imaging (MRI) for interventional procedures, such as guiding a medical device in the form of a catheter through a vessel to a target within a subject's body. In a typical MRI system, a subject is placed within the radio-frequency coils of an MRI scanner and the coils of the scanner generate a very strong static magnetic field (e.g. 0.5 Tesla) which causes the hydrogen nuclei in the part(s) of the subject within the magnetic field to align themselves with the field. This primary magnetic field is then modified by three superimposed gradients, one for each of the x, y and z directions, so as to provide a spatial modulation of the field which can then be used in signal localisation. Thus, a field gradient is imposed along the z-axis in the direction of the primary magnetic field such that a narrow plane of protons (i.e. hydrogen nuclei) resonate within a band of frequencies. A phase encoding gradient along the x-axis is activated for a short time during which the dipoles of the hydrogen nuclei acquire a different phase. A frequency encoding gradient along the y-axis is then activated to frequency encode the position of the dipoles while a receiver coil is activated to record the resultant signal. Once a sufficient number of spatially encoded samples of the imaging slice/volume have been collected, a 2D or 3D Fourier Transform (FT) algorithm is applied to the data in order to reconstruct the image slice/volume.

Referring to FIG. 1 of the drawings, it is known to use a catheter-based resonant circuit for MRI imaging. In the device illustrated, a resonant circuit 100 is mounted on the catheter tip, which circuit is physically connected to the amplifier/receiver hardware of an MRI scanner system. An imaging coil 102, in the form of an opposed solenoid, is provided at the distal end of the catheter and is connected to the resonant circuit 100.

As a result of modification by the three superimposed gradients of the primary magnetic field as described above, the magnetic moments of the hydrogen nuclei gyrate at a frequency proportional to the local magnetic field strength, which causes currents to be induced in the radio-frequency imaging coil 102. Signals representative of these induced currents are transmitted via the resonant circuit 100 to the image reconstruction module of the MRI scanner, so that the image slice/volume can be reconstructed in the manner described above, and then displayed.

Such catheter-based imaging method is described in, for example, U.S. Pat. No. 7,180,296.

As will be well known to a person skilled in the art, the size and shape of the inductor(s) in the catheter-based circuit determines the size and shape of the spatial region within which the MRI can be detected. For example, an opposed solenoid inductor (such as that used in the example given above) having a 3.5 mm diameter, will be able to image a region located in the gap between the solenoid windings of about 1.5 cm (wherein the radius of this region is perpendicular to the primary axis of the catheter). This opposed solenoid inductor configuration generates a spatial sensitivity profile which is well suited for imaging applications because it is ‘outward-looking’ i.e. its sensitivity is low inside the coil and larger in the region outside the coil. However, other suitable inductor configurations which generate distinct spatial sensitivity patterns will be known to a person skilled in the art. It is also known to use a catheter-based resonant circuit for active tracking, i.e. measuring/monitoring the 3D location and orientation of the catheter-tip. In this case, and referring back to FIG. 1 of the drawings, once again, a resonant circuit 100 is mounted on the catheter tip and connected to the amplifier/receiver hardware of an MRI scanner system, and an inductor is provided at the distal end of the catheter. Although the opposed solenoid 102 of FIG. 1 could be used for tracking (as opposed to imaging), when catheter-based resonant circuits are used for active tracking, it is desirable to use an inductor that has a more compact spatial sensitivity profile so that the location of the coil can be determined with more precision. U.S. Pat. No. 6,687,530, for example, describes a method and system for tracking small coils using magnetic resonance.

In conventional MRI systems, it is typically necessary for the operative performing an intervention to manually adjust the imaging location and acquisition parameters (e.g. slice position, slice thickness, tip angle/orientation, bandwidth, resolution, TE, TR (temporal resolution), field of view, etc) using a computer mouse or keyboard in combination with a graphical user interface. This can be cumbersome and makes this type of system unsuitable for intravascular MR guided procedures.

US Patent Application No. US2005/0054913 describes a method for automatically adjusting acquisition parameters based on the output of an adaptive tracking system. The system uses real-time tracking techniques to continually maintain the 3D position of a catheter tip, its orientation, insertion speed, and a combination of physiological parameters such as breathing rate, heart rate, etc; and the device position and orientation information is used to automatically adjust the scan plane for real-time imaging. Insertion speed may be used to automatically adjust pre-specified acquisition parameters in real-time.

However, the catheter coil is still required to be motionless during image acquisition because each successive phase-encoded bit of MRI data required to reconstruct an image must include the same anatomy. Motion during image acquisition securely impacts image quality by introducing blurring and artefacts.

It is therefore an object of the present invention to provide an improved catheter-based MRI imaging system which alleviates the above-mentioned problems and enables image data to be effectively collected and reconstructed during movement of the catheter.

### SUMMARY OF THE INVENTION

In accordance with the present invention, there is provided magnetic resonance imaging (MRI) apparatus, comprising:
one or more transmitting coils for generating a static magnetic field within which a subject can be positioned;
a probe for insertion into, and movement through, said subject, said probe including a tracking element;
an imaging coil
processing means for receiving tracking signals from said tracking element and spatially encoded image signals from said imaging coil, decoding said tracking signals from said tracking element to determine the relative position of said probe within an image volume and adjusting the image to be displayed accordingly corresponding to the said relative position of said probe, decoding said image signals from said imaging coil to generate an image for display, and updating said image to be displayed dynamically as said probe is moved within said subject based on tracking signals received from said tracking element and spatially encoded signals received from said imaging coil.

Thus, not only is the field of view (FoV) of the displayed image adjusted according to signals received from the tracking element, but the resolution can be controlled according to the speed at which the probe is moved through the subject. If the probe is moved quickly, the image quality will be relatively low (survey image) i.e. the signal-to-noise ratio and the resolution will be relatively low, whereas if the probe is moved more slowly, the processing means can update the displayed image dynamically using further signals received from the imaging coil (and tracking element), thereby increasing the resolution.

The present invention extends to an image processing module for a magnetic resonance imaging (MRI) system comprising one or more transmitting coils for generating a static magnetic field within which a subject can be positioned, an imaging coil and a probe for insertion into, and movement through, said subject, said probe including a tracking element, the image processing module being arranged and configured to receive spatially encoded signals from said imaging coil and tracking signals from said tracking element, decode said signals from said tracking element to determine the relative position of the probe within an image volume and adjust the image to be displayed accordingly corresponding to said relative position of the probe, decode the signals from said imaging coil to generate an image for display, and update said image to be displayed dynamically as said probe is moved through said subject based on tracking and spatially encoded signals received from said tracking element and said imaging coil respectively.

The present invention extends further to a method of generating an image for display of an image slice or volume within a subject using a magnetic resonance imaging (MRI) system including an imaging coil, the method comprising positioning a subject within a static magnetic field, spatially encoding said magnetic field, moving a probe through said subject, said probe including a tracking element, and collecting tracking signals from said tracking element and spatially encoded signals from said imaging coil provided in or on said probe, decoding said signals received from said tracking element, determining the relative location within an image volume of said probe using said signals collected from said tracking element and adjusting said image to be displayed accordingly corresponding said relative position of the probe, decoding said spatially encoded signals from said imaging coil to generate an image for display, and updating said image to be displayed dynamically as said probe is moved through said subject based on tracking and spatially encoded signals received from said tracking element and said imaging coil respectively.

In one exemplary embodiment, the imaging coil may be provided in or on the probe. However, this is not necessarily essential.

In a preferred embodiment, the signals from said tracking element and the image coil are collected or received in parallel. However, it is envisaged that, in some embodiments, it may be beneficial to alternate between tracking and imaging modes (i.e. to perform localisation of the probe within the image volume and updating the image in series, rather than in parallel.

Preferably, said tracking element comprises one or more coils located in or on said probe, and said tracking signals comprise spatially encoded signals received thereby. In one exemplary embodiment, the imaging coil is preferably located between two tracking elements in or on said probe, and the three coils are preferably connected to separate receive channels. The imaging coil may, for example, comprise an opposed solenoid imaging coil and the tracking coils may, for example, comprise respective loop coils. In a preferred embodiment, the spatially encoded signals are collected from said tracking coil and said imaging coil in respective successive sets of at least three from at least three respective projections within said image volume. The projections are preferably orthogonal relative to each other. At least three orthogonal projections are required in order to fully characterize the three-dimensional position of the tracking coils. Beneficially, the orthogonal projections from which a set of signals are collected are rotated relative to the orthogonal projections from which the previous set of signals was collected. Thus, each set of collected signals contributes new data to the image and the collection of redundant data is minimised.

In an exemplary embodiment, a Fourier Transform is applied to each of a set of signals collected via said tracking coils from respective projections and the location of the peak signal is determined to determine the relative position within said image volume of said probe. In a preferred embodiment, a one-dimensional Fourier Transform is applied separately to each of a set of signals collected via said imaging coil from respective projections, and the resultant image signals are back-projected into said image volume at the determined location of said probe.

In one exemplary embodiment, the transmitting coils are preferably configured to emit non-selective RF pulses. This is possible, because the sensitivity profile of the imaging coil will limit the field of view and avoid aliasing. However, in some embodiments it may be beneficial to use spatially selective excitation to position an image slice or volume that is centred on the imaging coil.

These and other aspects of the invention will be apparent from, and elucidated with reference to the embodiments described herein.

### BRIEF DESCRIPTION OF THE DRAWINGS

Embodiments of the present invention will now be described by way of examples only and with reference to the accompanying drawings in which:

FIG. 1 is a schematic diagram of a catheter-based MRI imaging system according to the prior art;

FIG. 2 is a schematic illustration of some of the principal components of a magnetic resonance imaging system;

FIG. 3 is a schematic diagram illustrating a catheter suitable for use in a system according to an exemplary embodiment of the present invention; and

FIG. 4 is a schematic flow diagram illustrating some of the principal steps of a method according to an exemplary embodiment of the present invention.

### DETAILED DESCRIPTION OF THE EMBODIMENTS

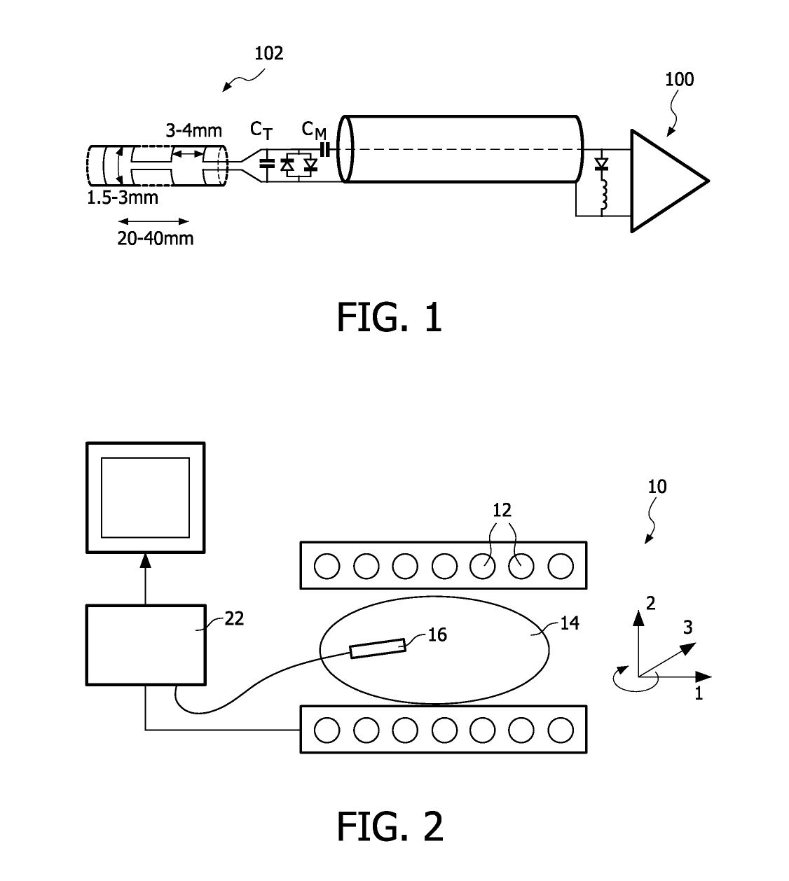

Referring to FIG. 1 of the drawings, a typical MRI system comprises an MRI scanner 10 having a plurality of radio-frequency transmit coils 12. A subject 14 undergoing an intravascular examination procedure is positioned within the scanner 10 as shown and the coils 12 generate a very strong static magnetic field. As explained above, this magnetic field excites the nuclear spins and realigns their magnetic moments away from the equilibrium position. A circuit (not shown) is provided for modifying the magnetic field by three super-imposed gradients, as described above.

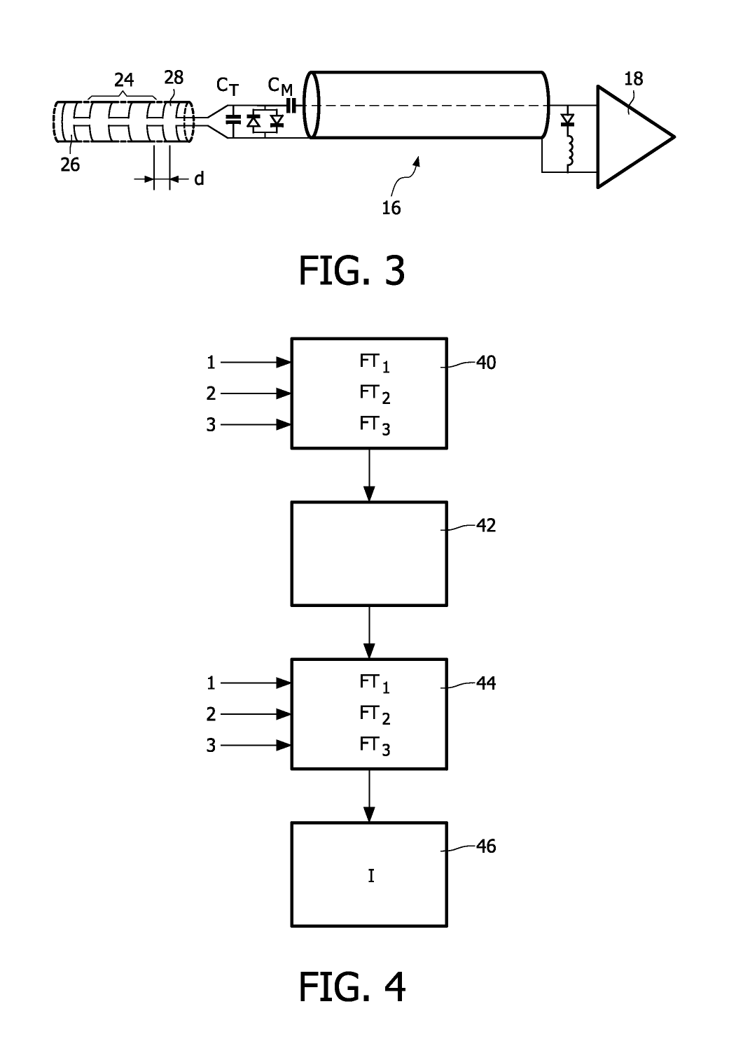

The system further comprises an endoscopic probe 16 which is inserted into the subject 14 via a small opening in the skin. Referring additionally to FIG. 3 of the drawings, an endoscopic probe 16 for use in a system according to an exemplary embodiment of the present invention comprises a tuned resonant circuit 18 mounted on the tip of the probe 16, which is capacitively coupled to the MRI scanner's amplifier/receiver hardware 22. In the illustrated example, the resonant circuit 18 is suitable for both imaging and device tracking. However, it will be appreciated that one or more separate resonant circuits may be provided to serve these two respective functions. Alternatively, one or more resonant circuits may be provided for imaging and an alternate device tracking technique may be used. It will, therefore, be appreciated by a person skilled in the art that the present invention is not necessarily intended to be limited in this regard.

An opposed-solenoid catheter-based imaging coil 24 is provided toward the distal end of the probe 16. As explained previously, the opposed-solenoid inductor configuration generates a spatial sensitivity profile which is well suited for imaging because it is ‘outward looking’ (i.e., its sensitivity is small inside the coil and larger in the region outside the coil).

However, it will be appreciated that other suitable inductor configurations exist which generate distinct spatial sensitivity patterns suitable for imaging, and the present invention is not necessarily intended to be limited in this regard.

Two loop coils 26, 28 are provided on the probe 16 to function as tracking markers. The coils are beneficially arranged on the probe 16 such that the imaging coil 24 is located directly between the tracking coils 26, 28, wherein the distance d between the imaging coil 24 and the tracking coils 26, 28 will be known. Thus, localising both of the tracking coils 26, 28 within the subject will allow the position and orientation of the imaging coil to be calculated. Each of the three coils 24, 26, 28 is, in this exemplary embodiment, connected to a separate receive channel (not shown) using specially designed inductors, so all tracking and imaging signals may be collected in parallel. Alternatively, however, different tracking technique (e.g. using the Faraday effect with polarized light) may be used.

In use, the transmit coils 16 of the MRI scanner emit spatially non-selective RF pulses to excite all of the anatomy located within the scanner (and maintain a steady-state). It is possible to use such non-selective excitation because the sensitivity profile of the imaging coil 24 will limit the filed of view (FoV) and avoid aliasing. It will be appreciated that the imaging parameters are ideally configured such that the sampled FoV is equal to or larger than the imaging coil's sensitivity region.

During the procedure, data is continually collected in respective groups of three orthogonal projections (in parallel) from each coil, wherein successive groups of three projections (1,2,3) are rotated relative to each other. Thus, each time another group of projections is collected, the 3D image volume is sampled more densely.

Each set of three projections is processed as a group, and each group is processed separately, as follows.

Referring additionally to FIG. 4, first the location within the image volume of the tracking markers 26, 28 is determined by analysing the signals from the tracking coils. For each group of three orthogonal projections, a Fourier Transform is applied to each projection (at step 40) and the location of the peak signal is determined (at step 42) to determine the relative position within the image volume of the tracking markers 26,28 (and, therefore, the imaging coil 24).

Next, at step 44, a 1D Fourier Transform is applied to the signals collected by the imaging coil 24 and these signals are individually back-projected into the image volume I (at step 46) at the appropriate location (determined using the above-mentioned tracking technique and previous knowledge of the relative locations of the imaging coil and tracking coils).

As explained above, when reconstructing magnetic resonance images using conventional techniques, in Fourier space, it is assumed that that the FOV that corresponds to each k-space line is the same (i.e. that the imaging coil does not move and the same image slice or volume is interrogated each time. In contrast, in the case of the present invention, the imaging coil and the position of the image volume moves each time a new set of 3 orthogonal projections is collected. It is important to collect the data in sets of three orthogonal projections so as to fully characterize the 3D position of the tracking markers, such that these markers can be accurately localize. Once the tracking markers and, therefore, the imaging coil have been localized, the position of the image volume of the image volume can be updated so that the next set of three orthogonal projects is centred correctly on the image coil at its new location.

These three orthogonal projections are also sampled with the image coil (in parallel with the sampling by the tracking coils) and the data sampled by the imaging coil is transformed into the image domain and used to update the reconstructed image volume. Each of the three projections is a 1D data set (i.e. a projection of the 3D image volume onto a 1D k-space line). Thus, a 1D Fourier transform can be applied to each projection separately to transform each projection into the image domain, following which, each transformed image signal can be back-projected into the reconstructed image volume at the appropriate location. In other words, the actual reconstruction process takes place in the image domain so that data from volumes that are translated relative to each other can be reconstructed together.

Successive sets of projections are rotated relative to each other so that the collection of redundant image data is minimised and each new set of projections contributes new information to the reconstructed image volume.

Thus, the system of the present invention continually monitors the location of a catheter-based imaging coil, such that image data collected using that coil can be mapped to the correct position within the reconstructed image volume. As a result, dynamic imaging with adaptive image quality is made possible because each bit of image data is added to the image volume separately, after a 1D Fourier Transform has been applied to the respective projection, and catheter tracking is used to position each new bit of image data within the reconstructed image volume. The present invention enables a user to continually collect MR image data while moving the catheter, without negatively impacting image quality. With this imaging method, 3D image volumes can be reconstructed, in real-time, such that moving the catheter through a portion of, for example, the subject's vasculature relatively slowly, will lead to relatively high quality (i.e. high signal-to-noise and high resolution) 3D images. Conversely, moving the catheter more rapidly through a portion of the vasculature will generate lower quality survey image volumes. The user can change speed dynamically, in order to adjust the resolution of the image volume accordingly, and also reverse directions and re-traverse a vessel segment in order to enhance the quality of a specific portion of the image volume. In other words, movement of the catheter automatically adjusts field of view of the image volume, and changing the speed of movement of the catheter automatically adjusts the resolution thereof, whereas in conventional systems, such acquisition parameters would need to be adjusted manually using a mouse, keyboard and graphical user interface.

By its very nature, it has been difficult to interrogate large portions of the vasculature and to inspect specific locations in detail using conventional MRI systems. Catheter-based MRI is a potentially powerful modality for detecting conditions such as atherosclerotic disease and assessing the vulnerability of atherosclerotic plaque. However, its potential has not yet been realised because current technology does not allow extended portions of the vasculature to be interrogated easily and because current catheter-based imaging methods are extremely sensitive to catheter motion (especially 3D imaging). On the other hand, the present invention enables MRI to be used to interrogate large portions of the vasculature and to inspect specific locations in detail by means of an intuitive control scheme. Thus, the present invention allows vascular MR imaging, for example, to be as simple to perform as competitive modalities such as intravascular ultrasound, and intravascular computed tomography.

It should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. The invention may be implemented by means of hardware comprising several distinct elements, and by means of a suitably programmed computer. In a device claim enumerating several means, several of these means may be embodied by one and the same item of hardware. The mere fact that certain measures are recited in mutually different dependent claims does not indicate that a combination of these measures cannot be used to advantage.

1. Magnetic resonance imaging (MRI) apparatus, comprising:
one or more transmitting coils for generating a static magnetic field within which a subject can be positioned;
a probe for insertion into, and movement through, said subject, said probe including a tracking element;
an imaging coil;
processing means for receiving tracking signals from said tracking element and spatially encoded image signals from said imaging coil, decoding said tracking signals from said tracking element to determine the relative position of said probe within an image volume and adjusting the image to be displayed accordingly corresponding to the said relative position of said probe, decoding said image signals from said imaging coil to generate an image for display, and updating said image to be displayed dynamically as said probe is moved within said subject based on tracking signals received from said tracking element and spatially encoded signals received from said imaging coil.

2. Apparatus according to claim 1, wherein said imaging coil is provided in or on said probe.

3. Apparatus according to claim 1, wherein said tracking signals from said tracking element and said spatially encoded image signals from said imaging coil are received in parallel by said processing means.

4. Apparatus according to claim 1, wherein said tracking element comprises one or more coils located in or on said probe and said tracking signals comprise spatially encoded signals received thereby.

5. Apparatus according to claim 2, wherein said imaging coil is located between two tracking elements in or on said probe.

6. Apparatus according to claim 5, wherein said tracking elements and said imaging coil are connected to said processing means via separate respective receive channels.

7. Apparatus according to claim 1, wherein said imaging coil comprises an opposed-solenoid imaging coil and said tracking elements comprise respective loop coils.

8. Apparatus according to claim 4, wherein said tracking signals are received from said tracking element and said spatially encoded image signals are received from said imaging coil in successive sets of at least three from at least three respective projections within said image volume.

9. An image processing module for a magnetic resonance imaging (MRI) system comprising one or more transmitting coils for generating a static magnetic field within which a subject can be positioned, an imaging coil and a probe for insertion into, and movement through, said subject, said probe including a tracking element, the image processing module being arranged and configured to receive spatially encoded image signals from said imaging coil and tracking signals from said tracking element, decode said signals from said tracking element to determine the relative position of the probe within an image volume and adjust the image to be displayed accordingly corresponding to said relative position of the probe, decode the signals from said imaging coil to generate an image for display, and update said image to be displayed dynamically as said probe is moved through said subject based on tracking and spatially encoded signals received from said tracking element and said imaging coil respectively.

10. A method of generating an image for display of an image slice or volume within a subject using a magnetic resonance imaging (MRI) system comprising an imaging coil, the method comprising positioning a subject within a static magnetic field, spatially encoding said magnetic field, moving a probe through said subject, said probe including a tracking element, and collecting tracking signals from said tracking element provided in or on said probe and spatially encoded signals from said imaging coil, decoding said signals received from said tracking element, determining the relative location within an image volume of said probe using said signals collected from said tracking element and adjusting the image to be displayed accordingly corresponding said relative position of the probe, decoding said spatially encoded signals from said imaging coil to generate an image for display, and updating said image to be displayed dynamically as said probe is moved through said subject based on tracking and spatially encoded signals received from said tracking element and said imaging coil respectively.
